(19) United States
(12) Patent Application Publication
(10) Pub. No.: US 2001/0045354 A1
(43) Pub. Date: Nov. 29, 2001

(54) Method of etching high aspect ratio openings in silicon

(76) Inventors: Yiqiong Wang, Morgan Hill, CA (US); Maocheng Li, Fremont, CA (US); Shaoher Pan, San Jose, CA (US)

Correspondence Address: Patent Counsel, Applied Materials, Inc, PO Box 450A, Santa Clara, CA, 95052, US

(21) Appl. No.: 09/882,141

(22) Filed: Jun. 15, 2001

Related U.S. Application Data
(62) Division of application No. 08/867,229, filed on Jun. 2, 1997.

(51) Int. Cl. C23C 14/00

(52) U.S. Cl. 204/192.37

(57) ABSTRACT

High aspect ratio openings can be etched in silicon having straight walls and rounded bottoms using as an etch gas a mixture including SF₆, HBr and O₂in a plasma chamber wherein the chamber is connected to an RF power source and the substrate is mounted on a support connected to a bias power source.

This invention relates to an etch composition for silicon-containing materials. More particularly, this invention relates to an etch composition that will anisotropically etch high aspect ratio openings having rounded bottoms and straight walls in silicon-containing materials.

### BACKGROUND OF THE INVENTION

In modern-day semiconductor processing of semiconductor devices, many devices are made in a single substrate. These devices are connected to each other by means of conductive lines. These conductive lines can introduce unwanted electric signals in the semiconductor substrate during operation of the devices, and so the devices must be separated from each other by some means of isolation. The usual means of isolation is to etch trenches between the devices that can be filled with a dielectric material, such as silicon oxide. Openings in silicon layers, such as polysilicon, are also etched for various semiconductor processes.

Further, in the manufacture of DRAMs, ultra-high aspect ratio deep trench capacitors are formed by reactive ion etching. It is important in making these structures that the sidewall taper control be as high as possible, i.e., so that the sidewalls of the trench are straight and perpendicular with respect to the substrate, to maximize the capacitor surface area.

However, as devices become smaller and are packed closer together, the trench etch needs to be made deeper, i.e., the aspect ratio, or depth to width of the opening, is required to be ever higher. In order to provide small diameter, deep openings that can later be filled with another material, the openings must have straight walls and they must have rounded bottoms so as to avoid the formation of voids near the bottom or along the sidewalls of the opening. In order to provide adequate isolation, the trench must be deeper than the depth of the devices to be isolated.

The trench depth will be limited if the selectivity between the etch mask and the silicon is inadequate, so that the etch mask is consumed before the desired depth of the trench is obtained. Also, if the sidewalls become tapered rather than straight, the bottom of the trench eventually will form a point, when etching will stop regardless of the desired depth. If during the etch processing too much material deposits on the sidewalls of the trench, the trench will close, leaving a void.

Various etchants for silicon-containing materials are known, such as halogen-containing gases, but all of them have various characteristics that made them inadequate as etchants for making small diameter, deep openings having straight walls. Some etch gases are isotropic rather than anisotropic; some deposit polymer-containing materials on the sidewalls; some of them produce bowed or shaped sidewalls that cannot be filled properly; some of them have low etch rates; and some of them require high chamber power that causes damage to or contamination of the substrates. Microloading is also a problem. Various combinations of etchants have also been tried, but the search for etchants that are highly selective with respect to a pattern mask, that will etch high aspect ratio, straight walled openings that have rounded bottoms in the substrate and that will etch silicon-containing material at high etch rates with minimal microloading has continued.

### SUMMARY OF THE INVENTION

We have found a particular etch composition that will produce high aspect ratio, straight walled openings in silicon that have rounded bottoms. The etch composition of the invention comprises a combination of a fluorine-containing gas such as sulfur hexafluoride, hydrogen bromide and oxygen. This etch composition will etch silicon-containing materials, particularly polysilicon or crystalline silicon, at high etch rates of 0.8 to 3 microns per minute.

### BRIEF DESCRIPTION OF THE DRAWING

FIG. 1 is a schematic cross sectional view of a plasma reactor in which the present etch of silicon-containing material can be carried out.

FIG. 2 is a graph of silicon etch rate versus chamber pressure.

FIG. 3 is a photomicrograph of openings in silicon made by the process of the present invention.

FIG. 4 is a photomicrograph of openings in silicon made by an etch composition outside of the invention.

FIG. 5 is a photomicrograph of openings in silicon made by varying the etching time of the etch composition of FIG. 4.

FIG. 6 is a photomicrograph of openings in silicon made by another etch composition outside of the invention.

FIG. 7 is a photomicrograph of openings in silicon made by still another etch composition outside of the invention.

FIG. 8 is a photomicrograph of openings in silicon made by yet another etch composition outside of the invention.

### DETAILED DESCRIPTION OF THE INVENTION

The present etch composition that will etch deep, high aspect ratio openings having rounded bottoms in silicon-containing material at high etch rates and with low microloading comprises a mixture of a fluorine-containing gas such as SF₆, together with HBr and O₂. The proportion of HBr to SF₆ in the etch mixture can be from about 0.1 to about 10.0, and is preferably about 0.5 to about 3. The combined HBr and SF₆ ratio to O₂ can vary from about 0.1 to about 10. Although no additional ingredients need be added, the addition of a noble gas, such as argon, can help smooth the sidewalls of the deepening trench. Other fluorine-containing gases can be substituted in whole or in part for SF₆, such as SiF₄, Si₂F₆and the like.

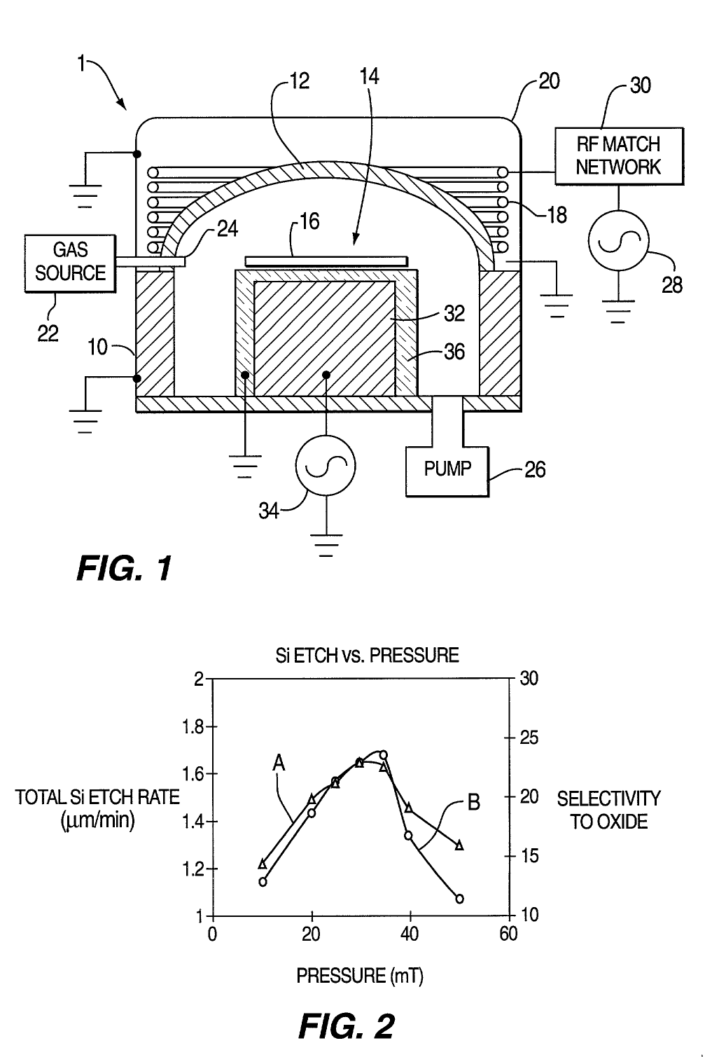

The present etch can be carried out suitably in a plasma reactor such as is shown in FIG. 1. This chamber is known as a decoupled plasma source chamber. Referring to FIG. 1, an inductively coupled RF plasma reactor includes a reactor chamber 1 having a grounded conductive cylindrical sidewall 10 and a shaped dielectric ceiling 12, e.g., dome-like. The reactor includes a wafer pedestal 14 for supporting a semiconductor wafer 16 in the center of the chamber 1; a cylindrical inductor coil 18 surrounding an upper portion of the chamber beginning near the plane of the top of the wafer or wafer pedestal 14 and extending upwardly therefrom toward the top of the chamber; a processing gas source 22 and a gas inlet 24 which can be a plurality of inlets spaced about the chamber, for furnishing a processing gas into the chamber interior; and a pump 26 for controlling the chamber pressure. The coil inductor 18 is energized by a plasma source power supply or RF generator 28 through a conventional active RF match network 30, the top winding of the coil inductor 18 being “hot” and the bottom winding being grounded. The wafer pedestal 14 includes an interior conductive portion 32 connected to a bias RF power supply or generator 34 and an exterior grounded conductor 36 (insulated from the interior conductive portion 32). A conductive grounded RF shield 20 surrounds the coil inductor 18. In accordance with one aspect of the chamber 1, uniformity of the plasma density spatial distribution across the wafer is improved by shaping the ceiling 12 as a multi-radius dome and individually determining or adjusting each one of the multiple radii of the ceiling 12. The multiple-radius dome shape in the embodiment of FIG. 1 somewhat flattens the curvature of the dome ceiling 12 around the center portion of the dome, the peripheral portion of the dome having a steeper curvature.

During processing, the power sources are turned on and processing gas passed into the chamber 1, forming a high density plasma in the chamber 1. The power to the chamber 1 from the inductive coil RF power source 28 is suitably up to about 3000 watts. The RF source can be a 12.56 MHz power source. The bias power to the substrate support 14 can vary up to 1000 watts, which provides a good etch rate. The bias frequency can vary from about 400 kHz up to about 13.56 MHz, but is preferably about 400 kHz. This provides improved profile control. However, the above frequencies are given for purposes of illustration only and different frequencies can be used. Frequencies as low as 50 kHz and up to 13.56 MHz and multiples thereof can also be employed.

During etching, the pressure is important; generally the etch rate increases with pressure, but it reaches a maximum and the etch rate decreases at pressures above that maximum level. The selectivity to the etch mask decreases above this maximum as well, as can be seen in FIG. 2. FIG. 2 is a graph of pressure in millitorr versus etch rate (curve A) and selectivity to oxide (curve B). This graph was generated by passing 50 sccm of SF₆, 50 sccm of HBr and 70 sccm of O₂ into the chamber of FIG. 1 using 800 watts of RF power to the coil and 30 watts of bias power. The substrate temperature was 10° C.

Thus if the pressure is too high, it is difficult to control the sidewall slope, and the etch becomes more isotropic. Although the etch can be carried out at pressures between about 1 to 100 millitorr, preferably a pressure of about 30 millitorr is employed.

Using a plasma reactor as described above, the power to the chamber from the inductive coil power source is suitably about 400 to about 1000 watts. The bias power to the substrate support can vary from about 20 to 100 watts, which provides a good etch rate.

The invention will be further described in the following Example and Controls. However, the invention is not meant to be limited to the details described therein.

### Example 1

A chamber as in FIG. 1 was connected to a 12.56 MHz power source. A 400 kHz power source was connected to the substrate support which was maintained at a temperature of about 20° C. A silicon wafer having a patterned layer of silicon oxide as an etch mask thereon was mounted on the substrate support electrode. The pressure was adjusted to 10 millitorr, and the power to 750 watts. A cleaning gas of 10 sccm of chlorine and 90 sccm of argon was passed into the chamber for 10 seconds.

The pressure was changed to 30 millitorr, the power to 700 watts, 25 watts of power was connected to the substrate support and an etch gas mixture of 40 sccm SF₆, 40 sccm HBr and 55 sccm of O₂ was passed into the chamber for 240 seconds.

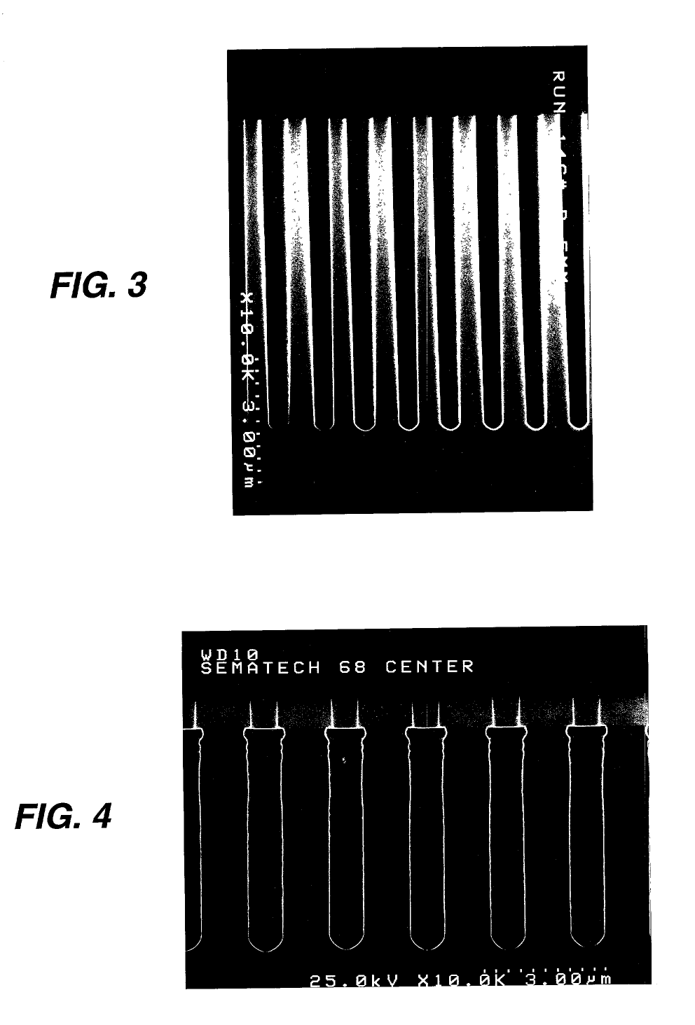

FIG. 3 is a photomicrograph of the resultant etched openings. It is apparent that the openings have straight walls and rounded bottoms. The taper angle is 87-89 degrees. The openings are free of any sidewall deposition. The aspect ratio is 14 and the openings have a diameter of 0.5 micron. The etch had a high selectivity between the etch mask and the silicon substrate.

The etch rate was 1.7 microns per minute. Etch uniformity or microloading across the wafer was excellent at ±3% with a selectivity to the oxide mask of 23. No mask faceting could be seen.

### Control 1

The procedure of Example 1 was repeated except using 750 watts of power and an etch gas mixture of 80 sccm SF₆ and 45 sccm O₂. As can be seen in the photomicrograph of FIG. 4, an isotropic etch was obtained and the trench diameter is wider than the mask opening. The etch rate was satisfactory at 2 microns/min.

### Control 2

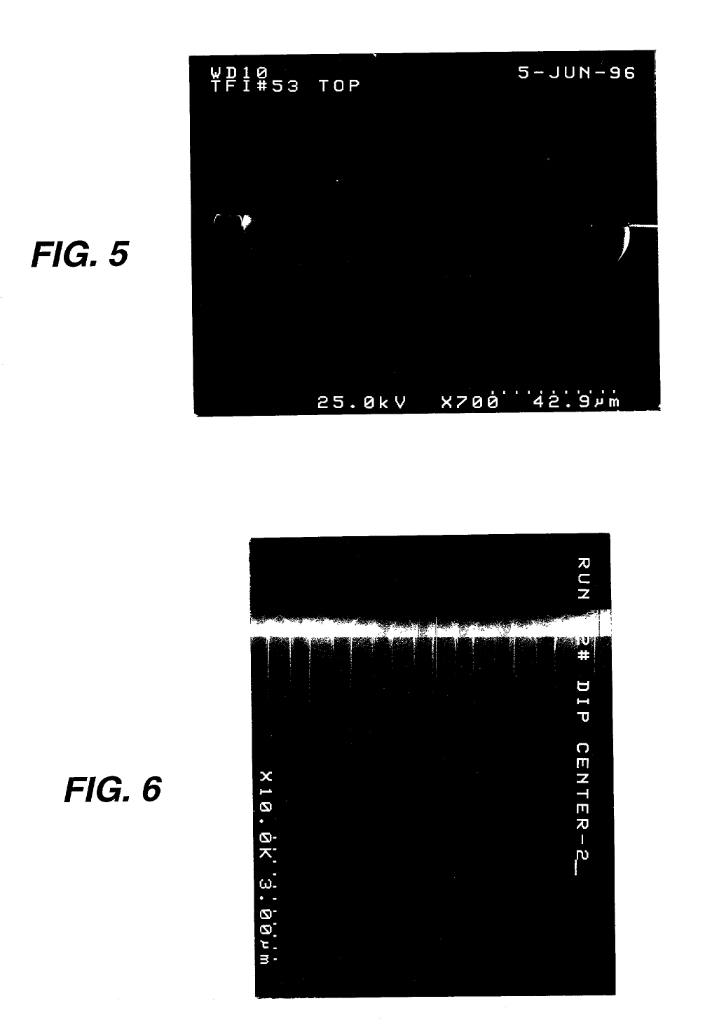

The procedure of Control 1 was repeated except the etch was continued for only 60 seconds. As can be seen in FIG. 5, initially a highly isotropic etch was obtained.

### Control 3

The procedure of Example 1 was repeated except using equal flow rates of HBr and O₂ as the etch gas. The etched openings had an aspect ratio of 10:1 and the sidewall profile is good, as can be seen in FIG. 6, but the etch rate was low, about 0.6 microns/min.

### Control 4

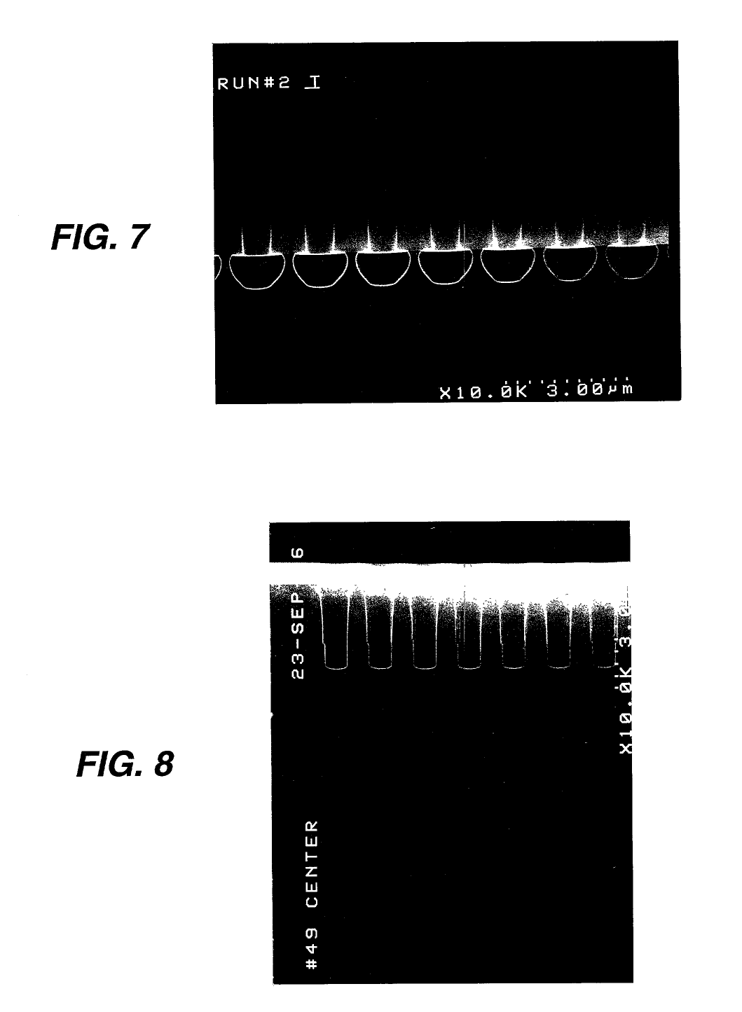

The procedure of Example 1 was repeated except using NF₃ and O₂ as the etch gas. The etch was highly isotropic, as shown in FIG. 7. Further, the etch rate was low, about 0.2 micron/min.

### Control 5

The procedure of Example 1 was repeated except using an etch gas mixture of CHF₃, SF₆ and O₂. As can be seen in FIG. 8, the sidewalls are rough, indicating some sidewall deposition, and the top of the openings displays some isotropy, the openings at the top having a wider diameter than the mask openings. Also the etch rate was low.

The etchant composition of the invention has been described by etching silicon, but the composition will etch other silicon-containing materials, such as silicon nitride, silicon oxide, silicon oxynitride, metal suicides such as titanium silicide, tungsten silicide and the like as well.

Although the invention has been described in terms of specific embodiments, the invention is not meant to be limited to those embodiments, but is only meant to be limited by the scope of the appended claims.

We claim:

1. An etch mixture for silicon comprising a fluorine-containing gas selected from the group consisting of SF₆, Si₂and together with HBr and oxygen.

2. An etch mixture according to claim 1 wherein the mixture additionally includes a noble gas.

3. An etch mixture according to claim 1 wherein the mixture contains SF₆.

4. An etch mixture according to claim 3 wherein the mixture additionally includes Si ₂ F₆ and SiF₄.

5. An etch mixture according to claim 3 wherein the volume ratio of HBr:SF₆ is 0.1 to 10.

6. An etch mixture according to claim 3 wherein the volume ratio of HBr and SF₆:O₂ is 0.1 to 10.

7. A method of etching deep, straight walled, rounded bottom openings in silicon comprising plasma etching a silicon substrate with an etch mixture comprising a fluorine-containing gas selected from the group consisting of SF₆, Si₂F₆ and SiF₄ together with HBr and O₂ in a plasma vacuum chamber, said silicon substrate mounted on a support electrode connected to an RF power source.

8. A method according to claim 7 wherein the fluorine-containing gas is SF₆.

9. A method according to claim 7 wherein the volume ratio of HBr:SF₆ is from 0.1 to 10.

10. A method according to claim 7 wherein the volume ratio of HBr and SF₆:O₂ is from 0.1 to 10.
